(19) United States
(12) Patent Application Publication
(10) Pub. No.: US 2004/0187297 A1
(43) Pub. Date: Sep. 30, 2004

(54) Method of fabricating a polymer resistor in an interconnection via

(75) Inventors: Te-Yeu Su, Taoyuan (TW); Hsin-Herng Wang, Hsin Chu (TW); Chien-Chang Huang, Taipei City (TW); Yu-Chou Yeh, Taichung City (TW)

Correspondence Address: MORGAN LEWIS & BOCKIUS LLP, 1111 PENNSYLVANIA AVENUE NW, WASHINGTON, DC, 20004, US

(73) Assignee: E Touch Corporation

(21) Appl. No.: 10/397,318

(22) Filed: Mar. 27, 2003

(51) Int. Cl. H01C 17/06; H05K 3/02; H01L 21/00

(52) U.S. Cl. 29/620; 29/852; 29/846

(57) ABSTRACT

A method of fabricating a polymer resistor in an interconnection via in a printed circuit board includes forming a plurality of first conductive traces on a substrate, forming an interconnection via through one of the first conductive traces in the substrate and terminating at a second conductive trace, filling polymer resistor paste in the interconnection via so as to contact the second conductive trace, thermally treating the polymer resistor paste to produce a polymer resistor, and forming a conductive layer in contact with the resistor and the one first conductive trace.

### RELATED APPLICATION

This application is related in subject matter to U.S. Application No.______ (Attorney Docket No. 054862-5001), filed concurrently herewith, and which is incorporated herein by reference.

### BACKGROUND OF THE INVENTION

1. Field of the Invention

The present invention relates to a method of fabricating a polymer resistor in an interconnection via, and more particularly, to a method of fabricating a polymer resistor in an interconnection via of a printed circuit board (PCB).

2. Discussion of the Related Art

FIG. 1 provides a cross-section of a typical circuit board 1 used in an electronic device, such as a cell phone, MP3 player, or personal digital assistant. The circuit board includes a circuit substrate S and a plurality of discrete components mounted on the top surface of the substrate S. The circuit substrate may be a printed circuit board having conductive traces to interconnect the discrete components mounted on the board. The discrete components typically include passive components and active components. The discrete components may include a resistor R, a capacitor C, and an inductor L. The active components may include integrated circuits (ICs), such as processors, application specific integrated circuits (ASICs), or other logic.

Consumers are demanding electronic products that are small and light weight, have reduced power consumption, and increased functionality. To meet this demand, the basic circuit board must be redesigned to accommodate a larger number of electronic components in a reduced area. Moreover, the manufacturing process for such a redesigned circuit board must be inexpensive, fast, efficient, and yield high quality electrical performance.

### SUMMARY OF THE INVENTION

Accordingly, the present invention is directed to a method of fabricating a polymer resistor in an interconnection via of a printed circuit board that substantially obviates one or more problems due to limitations and disadvantages of the related art.

An object of the present invention is to provide an inexpensive and efficient method of fabricating a polymer resistor in an interconnection via of a printed circuit board, in which the geometry and thickness of the resistor can be precisely controlled.

Another object of the present invention is to provide a method of fabricating a polymer resistor in an interconnection via of a printed circuit board having reduced signal path and precise resistance value.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method of fabricating a polymer resistor in an interconnection via in a printed circuit board includes forming a plurality of first conductive traces on a substrate, forming an interconnection via through one of the first conductive traces in the substrate and terminating at a second conductive trace, filling polymer resistor paste in the interconnection via so as to contact the second conductive trace, thermally treating the polymer resistor paste to produce a polymer resistor, and forming a conductive layer in contact with the resistor and the one first conductive trace.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a cross-sectional view of a PCB according to the related art;

FIGS. 2-3 are cross-sectional views of a PCB according to an exemplary embodiment of the present invention;

FIGS. 4-11 are cross-sectional views of a PCB according to another exemplary embodiment of the present invention;

FIG. 12 is a cross-sectional view of a PCB according to another exemplary embodiment of the present invention;

FIG. 13 is a flowchart of an exemplary method of fabricating a polymer resistor in an interconnection via of a PCB according to the present invention;

FIG. 14 is a flowchart of another exemplary method of fabricating a polymer resistor in an interconnection via of a PCB according to the present invention; and

FIG. 15 is a flowchart of another exemplary method of fabricating a polymer resistor in an interconnection via of a PCB according to the present invention.

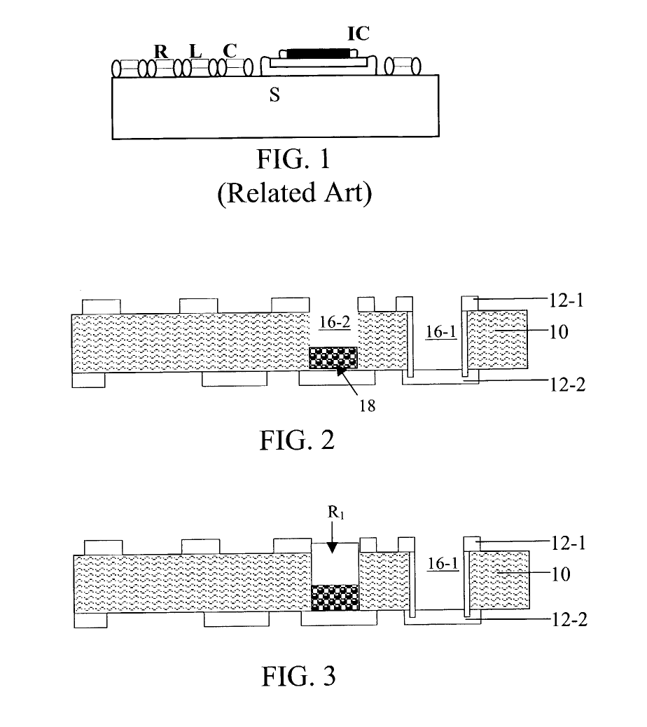

### DETAILED DESCRIPTION OF THE INVENTION

Reference will now be made in detail to the preferred embodiments of the present invention, examples of which are illustrated in the accompanying drawings.

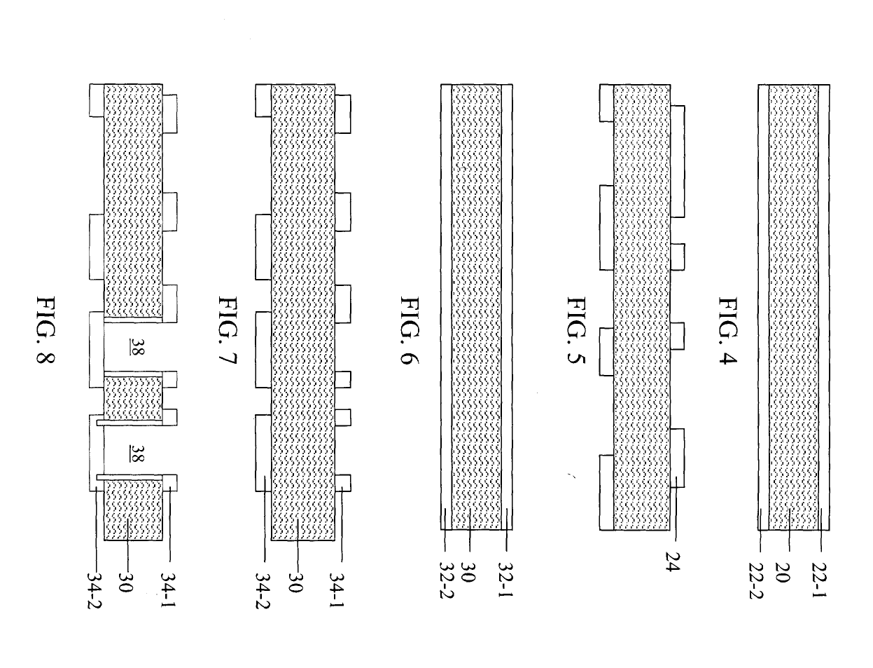

FIGS. 2-3 illustrate cross-sectional views of a PCB according to an exemplary embodiment of the present invention. In FIG. 2, conductive traces 12-1 and 12-2 may be formed on opposing surfaces of a PCB substrate 10. For example, the conductive traces 12-1 and 12-2 may be formed by a photolithographic patterning a conductive layer on the substrate 10. In this regard, a photoresist material may be formed over the conductive layer, developed into a pattern, and used as an etch mask to remove selected portions of the conductive layer and thereby produce traces 12-1 and/or 12-2. The remaining photoresist can then be removed. It should be appreciated that FIGS. 2 and 3 (as well as FIGS. 4-12) are illustrated in cross section and that conductive traces 12-1 and 12-2 extend over the top and bottom surfaces of the substrate 10.

In addition, via holes 16-1 and 16-2 may be selectively formed in the substrate 10. Via holes may be formed, for example, by laser drilling, mechanical drilling, or chemical etching. Internal surfaces of the via hole 16-1 may be coated with a conductive material to electrically connect a conductive trace 12-1 on a top surface of the substrate 10 and a conductive trace 12-2 on a bottom surface on the substrate 10. Alternatively, a polymer resistor pattern 18 may be formed inside the via hole 16-2. For example, instead of plating with a conductive material, polymer resistor paste may be printed inside or dispensed using a dispenser into the via hole 16-2 and on a conductive trace 12-2 to form the polymer resistor pattern 18. The polymer resistor pattern 18 may then be cured, for example, by a baking process to produce a resistor R₁. The polymer resistor pattern 18 may, but need not, undergo exposure to ultraviolet (UV) radiation to harden its surface and fix its shape.

The geometry of a resistor is a factor in determining its resistance value and, consequently, must be carefully controlled to ensure that the resistance value is within tolerance for the application. By dispensing the resistance paste in the via 16-2, the area of the resistor will be fixed by the dimensions of the via 16-2. Accordingly, the dimensions of the via 16-2, particularly the cross-sectional area of the via, should be carefully controlled during its formation. In addition, the volume of polymer resistance paste dispensed into the via 16-2 should be carefully controlled to produce the selected resistance value within tolerance. While it is possible to adjust the volume of polymer resistor paste dispensed to the size of the via, it may be simpler in some applications to control both the size of the via and the volume of paste. A dispenser may be used to dispense the correct volume of resistor paste, preferably avoiding problems, such as trapped air within the via, that would reduce the yield rate of the resistors so produced. A polymer resistor paste without or with limited aromatic solvent may be used to avoid imprecise volume fluctuations when the solvent evaporates.

In FIG. 3, a conductive material may be applied or dispensed onto resistor R₁ to form a resistor contact to a trace 12-1 on the top surface of the substrate 10. The conductive material may be the same material as the conductive traces 12-1 and 12-2, a conductive paste, or another conductive material. For example, a material may be selected that has a similar conductivity as the conductive traces 12-1 and 12-2. Accordingly, a resistor may be formed in a via of the substrate rather than on an uppermost surface thereof, thereby saving surface space for formation of other discrete components, such as IC chips, and/or a reduction in the size of the substrate. Forming the resistor in the via can also reduce signal path length, which permits an increase in operation speed, reduced power, and reduced electromagnetic interference.

FIGS. 4-11 illustrate cross-sectional views of a PCB according to another exemplary embodiment of the present invention. In FIG. 4, conductive layers 22-1 and 22-2 may be formed on opposing surfaces of a first substrate 20. The conductive layers 22-1 and 22-2 may be made of a conductive material, such as copper foil or other metal, or a metal alloy. In FIG. 5, conductive traces 24 may be formed on the first substrate 20, for example, by photolithographic patterning of the conductive layers 22-1 and 22-2, as described above

In FIG. 6, a second substrate 30 may also be prepared. For example, conductive layers 32-1 and 32-2 may be formed on opposing sides of the second substrate 30. The conductive layers 32-1 and 32-2 may be made of a conductive material, such as copper foil or other metal, or a metal alloy. In FIG. 7, conductive traces 34-1 and 34-2 may be formed on the second substrate 30, for example, by a photolithographic patterning-process of the conductive layers 32-1 and 32-2. Furthermore, in FIG. 8, via holes 38 may be selectively formed in the second substrate 30 and lined or filled with conductive material to electrically connect the conductive traces 34-1 and 34-2. As described above, the via holes 38 may be formed, for example, by laser drilling, mechanical drilling, or etching.

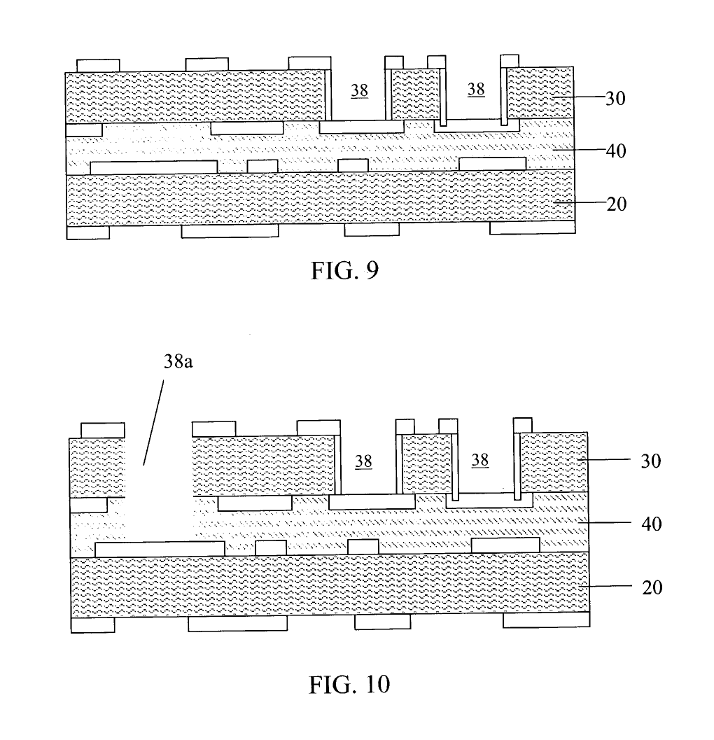

Moreover, in FIG. 9, the first and second substrates 20 and 30 may be stacked onto one another. An adhesive layer 40 may be inserted between the first and second substrate 20 and 30, such that the first and second substrates 20 and 30 may be affixed to each other with the adhesive layer 40 therebetween. The adhesive layer 40 may comprise, in whole or in part, an insulative material. In FIG. 10, an additional via hole 38a may be subsequently formed in the bonded structure, e.g., by laser drilling, mechanical drilling, or etching. For example, the via hole 38a may be formed to a conductive trace of the first substrate 20.

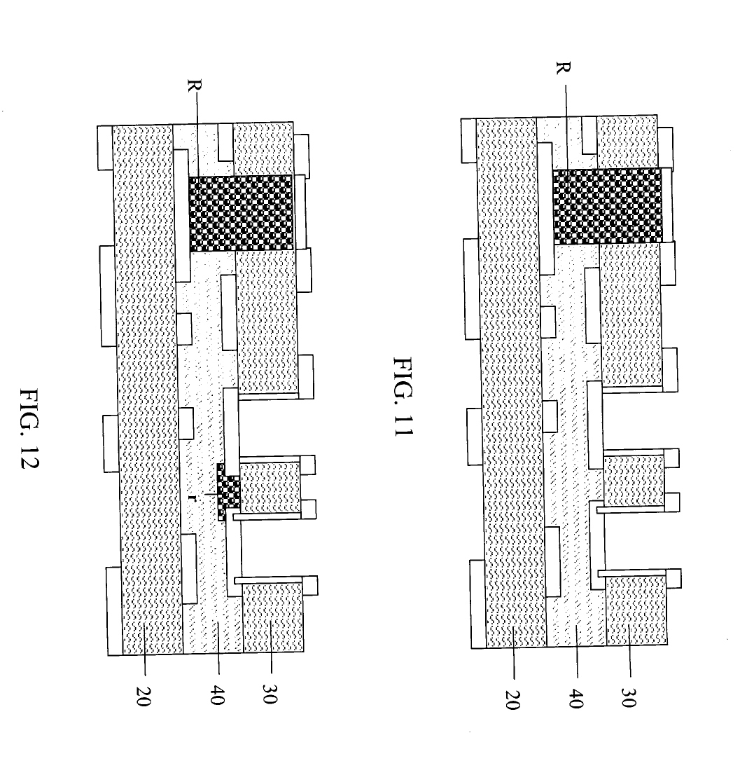

In FIG. 11, a resistor R may be formed inside the via hole 38a. For example, polymer resistor paste may be first dispensed in or printed onto the inside of the via holes 38a to form a polymer resistor pattern. For example, the polymer resistor paste may be applied using a dispenser or a jet-type head. The polymer resistor pattern may then be cured by a baking process to produce the polymer resistor R. Then, a conductive layer may be formed on or in contact with the resistor R, thereby forming the resistor contact. The polymer resistor pattern may, but need not, be subjected to a UV radiation process before undergoing the thermal baking process. Accordingly, resistors may be formed in vias, such as 38a, rather than on an uppermost surface of the bonded first and second substrates 20 and 30, thereby saving surface spaces for formation of other components and/or reducing the size of the substrate, among other advantages described herein.

FIG. 12 is a cross-sectional view of a PCB according to another exemplary embodiment of the present invention. In FIG. 12, a resistor r may also be embedded within the first and second substrates 20 and 30. For example, before bonding the first and second substrates 20 and 30, polymer resistor pastes may be printed between two conductive traces 34-3 on the second substrate 30, thereby forming a resistor pattern. The resistor pattern may then be hardened in a curing process to fix its shape and, therefore, its resistive value. The curing process may include exposure to UV radiation to harden the exposed surface of the resistive pattern, thereby fixing its shape. Following the UV radiation process, the hardened resistive pattern may be baked to activate the resistor.

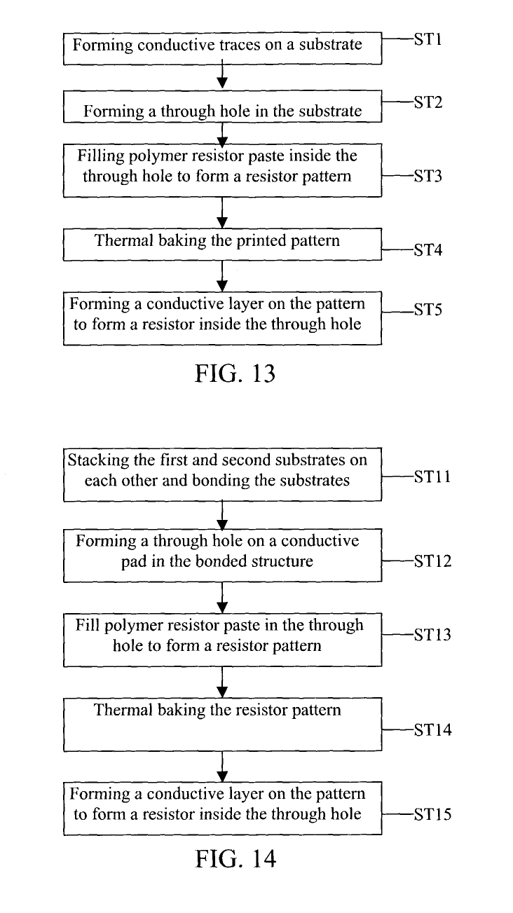

FIG. 13 is a flowchart of an exemplary method of fabricating a polymer resistor in an interconnection via of a PCB according to the present invention. The process shown in FIG. 13 may be used to produce the PCB shown in FIG. 3. As illustrated in FIG. 13, conductive traces may be formed on a substrate in ST1. As above, the substrate may be an insulative material, such as FR4 or other insulator, and conductive traces may be formed using a photolithographic process. In ST2, a through hole may be formed on one of the conductive traces in the substrate to a conductive trace on the opposite side of the substrate. The through hole may be formed by laser drilling, for example. The dimensions of the through hole are selected so that, when a resistor is formed therein, the resistor will exhibit a selected resistance value. In ST3, polymer resistor paste may be filled inside the through hole to form a polymer resistor pattern. The polymer resistor paste contacts the conductive trace on the opposite side of the substrate. In ST4, the polymer resistor pattern may be thermal baked to produce a resistor. The polymer resistor may, but need not, undergo an addition curing process, such as UV radiation process. Furthermore, in ST5, a conductive layer may be formed on or in contact with the resistor and with a trace on the surface of the substrate, thereby providing electrical connection to the resistor. Consequently, the polymer resistor inside the through hole. Accordingly, the polymer resistor inside the through hole may have precise resistance value based on the geometric shape of the polymer resistor pattern. It should be appreciated that ST4 and ST5 may be reversed so that the baking step is performed after the contact is formed.

FIG. 14 is a flowchart of another exemplary method of fabricating a polymer resistor in an interconnection via of a PCB according to the present invention. The process of FIG. 14 may be used to produce the PCB shown in FIG. 11. In FIG. 14, ST11, two substrates may be bonded together. For example, conductive traces may be formed on one or both surfaces of a first substrate. Conductive traces may be formed on one or both surfaces of a second substrate. The substrates may be made from an insulative material, such as FR4, and the conductive traces may be produced using a photolithographic process.

The second substrate may be stacked and affixed onto the first substrate to form a bonded structure. For example, an insulative adhesive layer may be interposed between the two substrates. In ST12, a through hole may be formed in one of the conductive traces of the bonded structure to another conductive layer either within or on the opposite side of the bonded structure. As above, the hole may be formed, for example, by laser drilling and may be sized to achieve a predetermined resistance value. In ST13, polymer resistor paste may be dispensed or printed inside the through hole to form a polymer resistor pattern in contact with the other conductive layer. The area of the resistor pattern in contact with the other conductive layer is determined by the sized of the through hole. In addition to the size of the through hole, the volume of polymer resistance paste dispensed in the through hole is selected to achieve a predetermined resistance value. In ST14, the polymer resistor pattern may then be baked to produce a resistor. Furthermore, in ST15, a conductive layer may be formed on or in contact with the polymer resistor and with the conductive trace on the surface of the substrate, thereby permitting electrical connection. Accordingly, the polymer resistor is formed inside the through hole and has a precise resistance value based on the geometric shape of the polymer resistor pattern. As discussed above in connection with FIG. 13, steps ST14 and ST15 may be reversed.

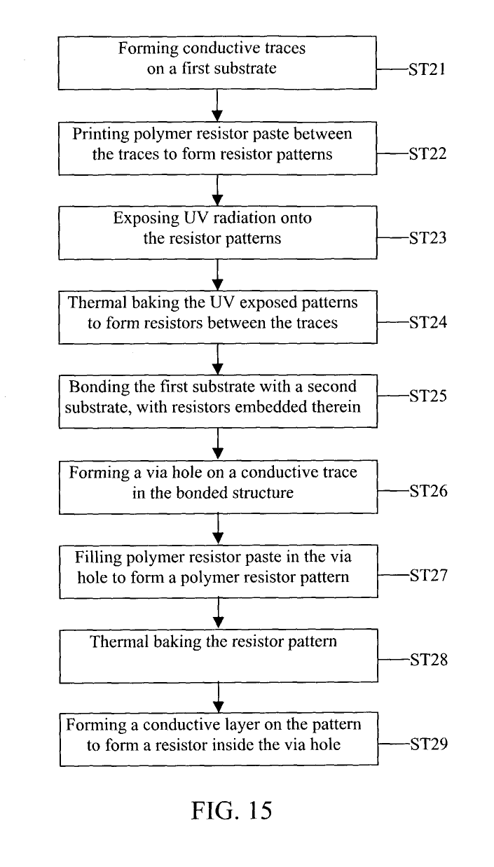

FIG. 15 is a flowchart of another exemplary method of fabricating a polymer resistor in an interconnection via of a PCB according to the present invention. The process of FIG. 15 may be used to form the PCB shown in FIG. 12. In FIG. 15, ST21, conductive traces are formed on a first substrate. ST21 may be performed as described above. In ST22, polymer resistor patterns may be printed between the conductive traces on the first substrate. As described above, the printed polymer resistor pattern may be exposed to UV radiation process in ST23, and then may undergo a thermal baking process in ST24 to form resistors on the first substrate. In ST25, the first substrate may be bonded to a second substrate, wherein the resistors on the first substrate are embedded therebetween.

Moreover, in ST26, a via hole may be formed in the bonded structure. For example, the via hole may be formed in one of the conductive traces on the first substrate and terminating at one of the conductive traces between the first and second substrates (e.g., on the opposite side of the first substrate or on the second substrate. Then, in ST27, polymer resistor paste may be printed inside the via hole to form a polymer resistor pattern. In ST28, the polymer resistor pattern may then be subjected to a baking process to form a polymer resistor inside the via hole. The polymer resistor may, but need not, undergo another curing process, such as a UV radiation process. It should be appreciated that step ST24 may be omitted if step ST28 is sufficient to activate the embedded resistors. As described above, the dimensions of the via and the volume of polymer resistor paste dispensed in the hole may be selected to produce a predetermined resistor value. In ST29, a conductive layer may be formed on or in contact with polymer resistor inside the via hole and with the conductive trace on the surface of the multi-layer structure. Steps ST28 and ST29 may be reversed. Accordingly, the polymer resistor inside the via hole may have precise resistance value based on the geometric shape of the polymer resistor pattern.

It will be apparent to those skilled in the art that various modifications and variations can be made in the method of fabricating a polymer resistor in an interconnection via of the present invention without departing from the spirit or scope of the invention. Thus, it is intended that the present invention cover the modifications and variations of this invention provided they come within the scope of the appended claims and their equivalents.

What is claimed is:

1. A method of fabricating a polymer resistor in an interconnection via in a printed circuit board, comprising:
forming a plurality of first conductive traces on a substrate;
forming an interconnection via through one of the first conductive traces in the substrate and terminating at a second conductive trace;
filling polymer resistor paste in the interconnection via so as to contact the second conductive trace;
thermally treating the polymer resistor paste to produce a polymer resistor; and
forming a conductive layer in contact with the resistor and the one first conductive trace.

2. The method according to claim 1, wherein the step of forming an interconnection via comprises forming the via of a predetermined size to produce a predetermined resistance value of the resistor.

3. The method according to claim 1, wherein the step of filling comprises filling the interconnection via with a predetermined volume of polymer resistor paste to produce a predetermined resistance value of said resistor.

4. The method according to claim 1, wherein the step of forming the conductive layer is performed before the thermally treating step.

5. The method according to claim 1, wherein the step of forming an interconnection via comprises laser drilling through the one first conductive trace and the substrate.

6. The method according to claim 1, wherein the step of forming an interconnection via comprises forming an interconnection through one of the first conductive traces on the substrate and terminating at a second conductive trace located on the opposite side of the substrate as the first conductive trace.

7. The method according to claim 1, wherein the step of forming an interconnection via comprises forming an interconnection through one of the first conductive traces on the substrate and terminating at a second conductive trace, wherein the second conductive trace is located within the substrate.

8. The method according to claim 1, wherein the step of filling comprises filling the interconnection via using a dispenser.

9. A method of fabricating a polymer resistor in an interconnection via of a multi-layer printed circuit board, comprising the steps of:
forming a plurality of first conductive traces on a first substrate;
bonding the first substrate with a second substrate to form a multi-layered printed circuit board;
forming an interconnection via in one of the first conductive traces in the multi-layered printed circuit board to a second conductive trace of the multi-layered printed circuit board;
filling polymer resistor paste in the interconnection via so as to contact the second conductive trace;
thermally treating the printed resistor pattern to produce a first resistor; and
forming a conductive layer in contact with the first resistor and the one first conductive trace.

10. The method according to claim 9, further comprising a step of forming a second resistor on the first substrate before the step of bonding, wherein said step of bonding comprises bonding the first and second substrates so that the second resistor is located between the first and second substrates.

11. The method according to claim 10, wherein the step of forming the second resistor comprises printing second polymer resistor paste between and in contact with two of the first conductive traces on the first substrate, exposing the second polymer resistor paste to ultraviolet (UV) radiation to harden a surface thereof and thereby fix the shape of the second polymer resistor paste, and thermally treating the second polymer resistor paste to produce the second resistor.

12. The method according to claim 9, further comprising a step of forming a second resistor on the second substrate before the step of bonding, wherein said step of bonding comprises bonding the first and second substrates so that the second resistor is located between the first and second substrates.

13. The method according to claim 12, wherein the step of forming the second resistor comprises printing second polymer resistor paste between and in contact with two conductive traces on the second substrate, exposing the second polymer resistor paste to ultraviolet (UV) radiation to harden a surface thereof and thereby fix the shape of the second polymer resistor paste, and thermally treating the second polymer resistor paste to produce the second resistor.

14. The method according to claim 9, wherein the step of forming an interconnection via comprises forming the via of a predetermined size to produce a predetermined resistance value of the first resistor.

15. The method according to claim 9, wherein the step of filling comprises filling the interconnection via with a predetermined volume of polymer resistor paste to produce a predetermined resistance value of said first resistor.

16. The method according to claim 9, wherein the step of forming the conductive layer is performed before the thermally treating step.

17. The method according to claim 9, wherein the step of forming an interconnection via comprises laser drilling through the one first conductive trace and the first substrate.

18. The method according to claim 9, wherein the step of forming an interconnection via comprises forming an interconnection through one of the first conductive traces on the first substrate and terminating at a second conductive trace located on the opposite side of the first substrate as the first conductive trace.

19. The method according to claim 9, wherein the step of forming an interconnection via comprises forming an interconnection through one of the first conductive traces on the first substrate and terminating at a second conductive trace on the second substrate.
